(19) United States
(12) Patent Application Publication
(10) Pub. No.: US 2011/0057514 A1
(43) Pub. Date: Mar. 10, 2011

(54) POWER METER WITH TRANSFER SWITCH

(75) Inventors: Todd Matthew LATHROP, Oakdale, PA (US); Samuel E. FAYLO, Oakdale, PA (US); David Richard WELSH, Buchanan, MI (US)

(73) Assignee: EATON CORPORATION, Cleveland, OH (US)

(21) Appl. No.: 12/555,191

(22) Filed: Sep. 8, 2009

(51) Int. Cl. H02J 1/00; G01R 11/32

(52) U.S. Cl. 307/64; 324/142

(57) ABSTRACT

Apparatus and methods for providing a capability to perform automatic switching between a primary and secondary power source and primary source metering in the same meter enclosure.

### BACKGROUND

Today more and more residential and commercial sites are employing some type of secondary, or back-up, power source to protect against utility power outages. When the secondary power source is installed, a transfer switch is also installed to provide a switchable connection between the utility power source and the load or the secondary power source and the load. The installation of the transfer switch typically involves installing a separate panel near a utility meter through which the utility power enters the building.

### SUMMARY

An electric power control apparatus is provided that includes a meter enclosure defining a compartment and a display opening configured to fit a display associated with an electric power meter. The enclosure further defines a first entrance configured to allow passage of a primary conductor carrying electric power from a primary power source, a second entrance configured to allow passage of a secondary conductor carrying electric power from a secondary source, and an exit configured to allow passage of a load conductor carrying electric power to a load. An automatic transfer switch is mounted within the meter enclosure that is electrically connected to the primary conductor, the secondary conductor, and the load conductor to selectively provide a power flow path between the primary conductor and the load or the secondary conductor and the load. The automatic transfer switch includes a contactor set that selectively electrically connects the load conductor to either the primary conductor or the secondary conductor and a switching logic that senses power on the primary conductor and controls the contactor set to electrically connect the load conductor to either the primary conductor or the secondary conductor based on the sensed power on the primary conductor or the secondary conductor.

An electric power meter is disposed between the primary power source and the load and is mounted within the enclosure. The electric power meter includes a display that is fitted within the display opening. The meter is operable to measure an accumulated amount of power that has been provided on the primary conductor to the load and to display the accumulated amount of power on the display.

A primary power disconnect mechanism and/or a secondary power disconnect mechanism may be mounted within the meter enclosure. A status indicator may be disposed on an outer surface of the meter enclosure to communicate a present operating status of the electric power control apparatus. For example, the status indicator may communicate which of the primary conductor or secondary conductor is connected, via the automatic transfer switch, to the load conductor.

The transfer switch's switching logic may include a computer-readable medium storing computer executable switch actuation instructions and a microprocessor configured to read and execute the instructions. The switching logic may be configured to disconnect the primary conductor from the load conductor and to connect the secondary conductor to the load conductor when the sensed power on the primary conductor falls outside of a range of acceptable power quality. The switching logic may be configured to send a start signal to the secondary power source when the sensed power on the primary conductor falls outside of a range of acceptable power quality. The switching logic may be configured to disconnect the secondary conductor from the load conductor and to connect the primary conductor to the load conductor when the sensed power on the primary conductor falls within a range of acceptable power quality.

### BRIEF DESCRIPTION OF THE DRAWINGS

The accompanying drawings, which are incorporated in and constitute a part of the specification, illustrate various example systems, methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 is a schematic diagram of a prior art electric power control system.

FIG. 2 is a schematic diagram of an example embodiment of an electric power control apparatus.

FIG. 3 is a schematic diagram of an example embodiment of an electric power control apparatus.

### DETAILED DESCRIPTION

Referring to FIG. 1, a prior art electric power control system 10 is illustrated. The electric power control system controls power flowing to a load 60 on a load conductor 55 from either a utility power source (not shown) provided on a primary conductor 15 or a secondary power source 50 provided on a secondary conductor 45. The electric power control system 10 includes an electric power meter 20 that meters the amount of power that has been supplied on the primary conductor 15 from a utility, a main disconnect 30 used to disconnect primary power from the load 60, and a transfer switch mechanism 40. The meter 20, main disconnect 30, and transfer switch 40 are separate from one another and require separate installation.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Therefore, the invention is not limited to the specific details, the representative apparatus, and illustrative examples shown and described. Thus, this application is intended to embrace alterations, modifications, and variations that fall within the scope of the appended claims.

To the extent that the term “includes” or “including” is employed in the detailed description or the claims, it is intended to be inclusive in a manner similar to the term “comprising” as that term is interpreted when employed as a transitional word in a claim.

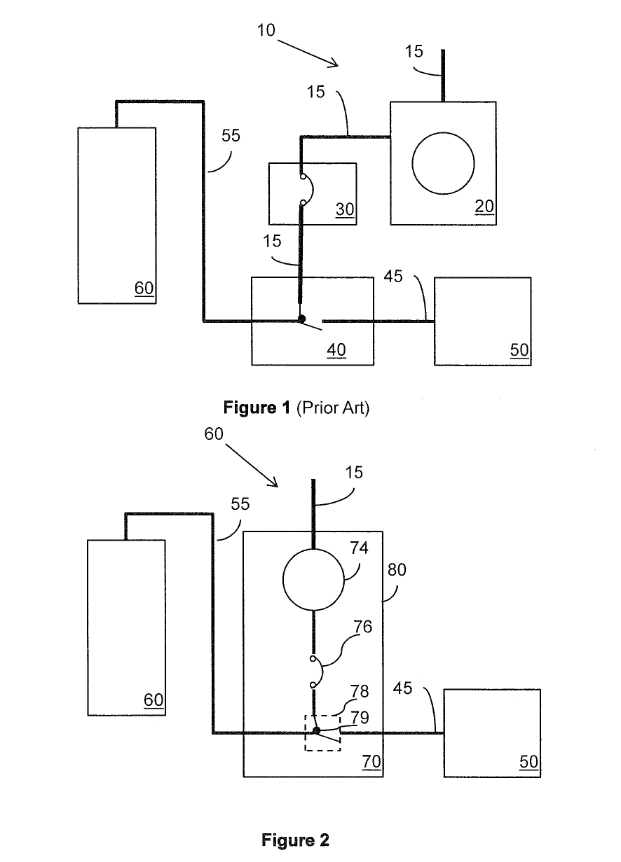

Referring to FIG. 2, an electric power control system 70 is illustrated. The electric power control system 70 controls the flow of power from a primary power source such as, for example, a utility to a load 60. The load 60 may be, for example, a main circuit breaker panel for a residence or building. Power from the primary source flows to the load 60 on a primary conductor 15 through an electric power control apparatus 70. The electric power control apparatus 70 includes an electric power meter 74, a primary breaker 76, and an automatic transfer switch 78 all mounted and electrically connected to one another within a same enclosure 80. The enclosure 80 defines an inner chamber in which the components are mounted as well as an opening for a meter display and the primary, secondary, and load conductors 15, 45, 55.

The electric power meter 74 measures, accumulates, and displays an amount of power that has been supplied to the load on the primary conductor 15. Power from the electric power meter 74 flows to the primary breaker 76. The primary breaker 76 is used to manually disconnect the path from the primary power source to the load 60. The primary breaker 76 may also automatically open in the event of power overload on the primary conductor 15.

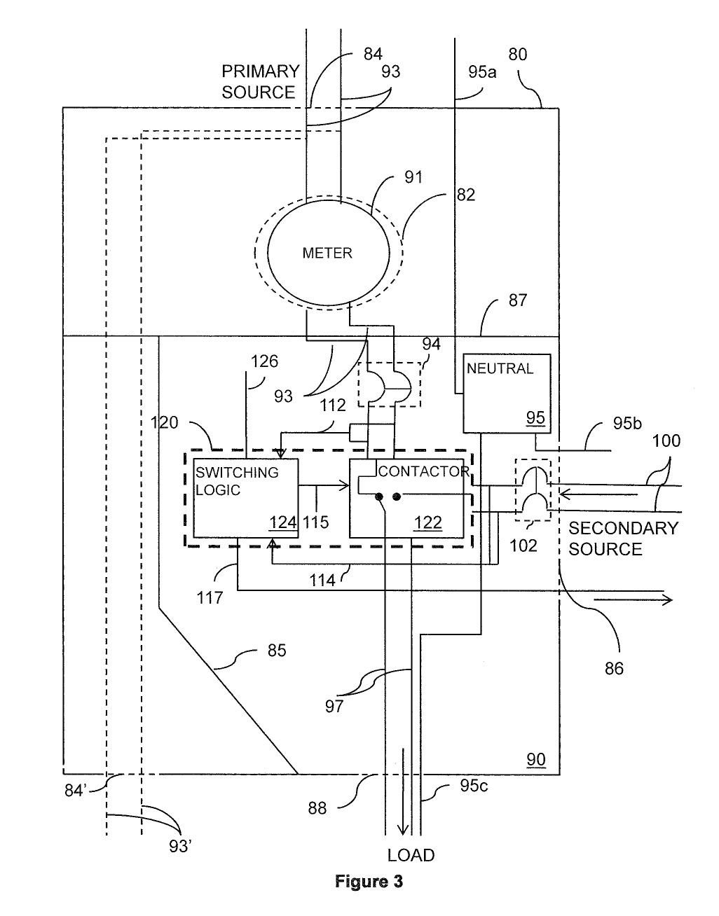

Within the enclosure 80, the primary breaker 76 is electrically connected to an automatic transfer switch mechanism 78. The automatic transfer switch includes an electrical contactor 79 that selectively connects either the primary power source or a secondary power source 50 to the load 60. The transfer switch includes a control mechanism (shown in FIG. 3), such as, for example, a microprocessor based controller to monitor the quality of the primary power. The control mechanism actuates the electrical contactor 79 to disconnect the load from the primary power source when the quality of the primary power is not satisfactory. A load conductor 55 routes power from the transfer switch to the load 60. The secondary power source 50 is also electrically connected to the automatic transfer switch 78 by way of a secondary conductor 45. The automatic transfer switch is operable to connect the secondary conductor 45 to the load conductor 55 when the primary conductor has been disconnected from the load conductor. The automatic transfer switch 78 thus connects either the primary power source or the secondary power source, but not both simultaneously, to the load 60.

“Computer-readable medium”, as used herein, refers to a medium that stores signals, instructions and/or data. A computer-readable medium may take forms, including, but not limited to, non-volatile media, and volatile media. Non-volatile media may include, for example, optical disks, magnetic disks, and so on. Volatile media may include, for example, semiconductor memories, dynamic memory, and so on. Common forms of a computer-readable medium may include, but are not limited to, a floppy disk, a flexible disk, a hard disk, a magnetic tape, other magnetic medium, an ASIC, a CD, other optical medium, a RAM, a ROM, a memory chip or card, a memory stick, and other media from which a computer, a processor or other electronic device can read.

“Logic”, as used herein, includes but is not limited to hardware, firmware, software in execution on a machine, and/or combinations of each to perform a function(s) or an action(s), and/or to cause a function or action from another logic, method, and/or system. Logic may include a software controlled microprocessor, a discrete logic (e.g., ASIC), an analog circuit, a digital circuit, a programmed logic device, a memory device containing instructions, and so on. Logic may include one or more gates, combinations of gates, or other circuit components. Where multiple logical logics are described, it may be possible to incorporate the multiple logical logics into one physical logic. Similarly, where a single logical logic is described, it may be possible to distribute that single logical logic between multiple physical logics.

“Software”, as used herein, includes but is not limited to, one or more executable instruction that cause a computer, processor, or other electronic device to perform functions, actions and/or behave in a desired manner. “Software” does not refer to stored instructions being claimed as stored instructions per se (e.g., a program listing). The instructions may be embodied in various forms including routines, algorithms, modules, methods, threads, and/or programs including separate applications or code from dynamically linked libraries.

FIG. 3 is a more detailed schematic illustration of an electric power control apparatus 90 that functions in a similar manner to the electric power control apparatus 79 of FIG. 2. The electric power control apparatus 90 includes an enclosure 80 that houses the electrical components that are part of the apparatus. The enclosure defines a display opening 82 on a front face configured to fit a display on a utility meter. The enclosure 80 defines a first entrance 84 that allows passage of primary conductors 93. In some embodiments, an alternate primary power conductor entrance 84′ is provided in addition to allow passage of primary conductors 93′. The two entrances 84 and 84′ may both be provided as knock out portions so that the enclosure may be adapted to receive primary power conductors from two different directions. The enclosure 80 also defines a second entrance 86 that allows passage of secondary conductors 100 and a load exit 88 that allows passage of load conductors 97. In the illustrated embodiment, the enclosure includes two interior walls, a first wall 85 that defines a gutter that can accommodate the primary conductors 93, and a second wall 87 that defines a compartment for the electric power meter 91 and primary conductors 93 or 93′. In the illustrated embodiment, a neutral connection module 95 is provided within the enclosure to provide a connection point for neutral conductors 95a, 95b, 95c associated with each of the primary conductors 93, the secondary conductors 100, and the load conductors 97, respectively. The electric power meter 91 is electrically connected between the primary source and an automatic transfer switch 120 that will be described in more detail below. The electric power meter 91 includes a display (not shown) that is fitted within the display opening 82. The automatic transfer switch 120 includes a switching logic 124 and a contactor 122. The contactor 122 is configured to connect either the primary conductors 93 or the secondary conductors 100, but not both simultaneously, to the load conductors 97. The contactor 122 may be, for example, a relay or solid state device or any other suitable mechanism. The switching logic includes a microprocessor that is programmed to control the contactor 122 according to a control algorithm. The switching logic may thus be implemented as a circuit board that includes power and input conditioning components along with a processor and memory (or ASIC).

The switching logic 124 monitors the status of the primary power source as shown at 112 as well as the status of secondary power source as shown at 114. The switching logic 124 controls the contactor 122 based on the status of these two inputs. For example, when the quality (such as a power level) of the primary power falls outside of a predetermined range, the switching logic actuates the contactor 122 to disconnect the load conductors 97 from the primary conductors 93 and to connect the load conductors 97 to the secondary conductors 100. In some embodiments, when the switching logic 124 switches to the secondary power source, the switching logic 124 also provides a start signal as shown at 117 to the secondary power source. For example, this start signal 117 may cause a generator that is being used as a secondary power source to start up and begin supplying power.

The switching logic may continuously monitor the primary power source and actuate the contactor 122 to connect the primary conductors 93 to the load when the primary power source is supplying power at a level within a predetermined range of quality. The switching logic may also disconnect the secondary conductor from the load if it is detected that the secondary power source is providing power outside of a predetermined range. The switching logic 124 may also control a status indicator 126, such as, for example, one or more LEDs, that communicates which of the primary or secondary source is presently connected to the load.

In some embodiments, the electric power control apparatus includes a primary breaker 94 and a secondary breaker 102 that can be manually operated to disconnect the primary conductors 93 and the secondary conductors 100, respectively. The electric power control apparatus 90 can be installed by simply mounting the enclosure 80 to a building and connecting the primary conductors 93, the secondary conductors 100 and the load conductors 97 to the electric power control apparatus 90.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Therefore, the invention is not limited to the specific details, the representative apparatus, and illustrative examples shown and described. Thus, this application is intended to embrace alterations, modifications, and variations that fall within the scope of the appended claims.

What is claimed is:

1. An electric power control apparatus comprising:
a meter enclosure defining a compartment, the meter enclosure further defining a display opening configured to fit a display associated with an electric power meter, the enclosure further defining a first entrance configured to allow passage of a primary conductor carrying electric power from a primary power source, a second entrance configured to allow passage of a secondary conductor carrying electric power from a secondary source, and an exit configured to allow passage of a load conductor carrying electric power to a load;
an automatic transfer switch mounted within the meter enclosure, the automatic transfer switch being electrically connected to the primary conductor, the secondary conductor, and the load conductor to selectively provide a power flow path between the primary conductor and the load or the secondary conductor and the load, the automatic transfer switch comprising:
a contactor that selectively electrically connects the load conductor to either the primary conductor or the secondary conductor; and
a switching logic that senses power on the primary conductor and controls the contactor to electrically connect the load conductor to either the primary conductor or the secondary conductor based on the sensed power on the primary conductor; and
an electric power meter disposed between the primary power source and the load and mounted within the enclosure, the electric power meter including a display that is fitted within the display opening, the electric power meter being operable to measure an accumulated amount of power that has been provided on the primary conductor to the load and to display the accumulated amount of power on the display.

2. The electric power control apparatus of claim 1 comprising a primary power disconnect mechanism mounted within the meter enclosure, the primary power disconnect mechanism operable, when actuated, to disconnect the primary power conductor from the load conductor to prevent flow of power from the primary power source to the load conductor.

3. The electric power control apparatus of claim 1 comprising a secondary power disconnect mechanism mounted within the meter enclosure, the secondary power disconnect mechanism operable, when actuated, to disconnect the secondary power conductor from the load conductor to prevent flow of power from the secondary power source to the load conductor.

4. The electric power control apparatus of claim 1 comprising a status indicator disposed on an outer surface of the meter enclosure, the status indicator comprising one or more status indicating mechanisms configured to communicate a present operating status of the electric power control apparatus.

5. The electric power control apparatus of claim 4 where at least one of the status indicating mechanisms is configured to communicate which of the primary conductor or secondary conductor is connected, via the automatic transfer switch, to the load conductor.

6. The electric power control apparatus of claim 1 where the switching logic comprises a computer-readable medium storing computer executable switch actuation instructions and a microprocessor configured to read and execute the instructions.

7. The electric power control apparatus of claim 1 where the switching logic is configured to disconnect the primary conductor from the load conductor and connect the secondary conductor to the load conductor when the sensed power on the primary conductor falls outside of a range of acceptable power quality.

8. The electric power control apparatus of claim 1 where the switching logic is configured to send a start signal to the secondary power source when the sensed power on the primary conductor falls outside of a range of acceptable power quality.

9. The electric power control apparatus of claim 1 where the switching logic is configured to disconnect the secondary conductor from the load conductor and to connect the primary conductor to the load conductor when the sensed power on the primary conductor falls within a range of acceptable power quality.

10. An electric power control apparatus comprising:
a meter enclosure defining a compartment, the meter enclosure further defining a display opening configured to fit a display associated with an electric power meter, the enclosure further defining a first entrance configured to allow passage of a primary conductor carrying electric power from a primary power source, a second entrance configured to allow passage of a secondary conductor carrying electric power from a secondary source, and an exit configured to allow passage of a load conductor carrying electric power to a load;
an automatic transfer switch mounted within the meter enclosure, the automatic transfer switch being electrically connected to the primary conductor, the secondary conductor, and the load conductor to selectively provide a power flow path between the primary conductor and the load or the secondary conductor and the load, the automatic transfer switch comprising:
a contactor that selectively electrically connects the load conductor to either the primary conductor or the secondary conductor; and
switching logic comprises a computer-readable medium storing computer executable switch actuation instructions and a microprocessor configured to read and execute the instructions, the instructions comprising sensing power on the primary conductor and controlling the contactor set to electrically connect the load conductor to either the primary conductor or the secondary conductor based on the sensed power on the primary conductor;
a primary power disconnect mechanism mounted within the meter enclosure, the primary power disconnect mechanism operable, when actuated, to disconnect the primary power conductor from the load conductor to prevent flow of power from the primary power source to the load conductor;
a status indicator disposed on an outer surface of the meter enclosure, the status indicator comprising one or more status indicating mechanisms configured to communicate a present operating status of the electric power control apparatus and
an electric power meter mounted within the enclosure, the electric power meter including a display that is fitted within the display opening, the meter further being configured to measure an accumulated amount of power that has been provided on the primary conductor and to display the accumulated amount of power on the display.

11. The electric power control apparatus of claim 10 comprising a secondary power disconnect mechanism mounted within the meter enclosure, the secondary power disconnect mechanism operable, when actuated, to disconnect the secondary power conductor from the load conductor to prevent flow of power from the secondary power source to the load conductor.

12. The electric power control apparatus of claim 10 where at least one of the status indicating mechanisms is configured to communicate which of the primary conductor or secondary conductor is connected, via the automatic transfer switch, to the load conductor.

13. The electric power control apparatus of claim 10 where the switch actuation instructions include disconnecting the primary conductor from the load conductor and connecting the secondary conductor to the load conductor when the sensed power on the primary conductor falls outside of a range of acceptable power quality.

14. The electric power control apparatus of claim 10 where the switch actuation instructions include sending a start signal to the secondary power source when the sensed power on the primary conductor falls outside of a range of acceptable power quality.

15. The electric power control apparatus of claim 10 where the switch actuation instructions include disconnecting the secondary conductor from the load conductor and connecting the primary conductor to the load conductor when the sensed power on the primary conductor falls within a range of acceptable power quality.

16. An electric power control system comprising:
means for monitoring a quality of primary power being supplied by a primary power source;
means for automatically electrically connecting an electrical load to either a primary power source or a secondary power source based on the monitored quality of primary power;
means for measuring and displaying an amount of electric power that has been supplied by the primary power source to the electrical load;
means for manually disconnecting the primary power source from the electrical load; and
where the means for measuring, means for automatically connecting, means for measuring and displaying, and means for manually disconnecting are housed within a same enclosure.
